(19) United States
(12) Patent Application Publication
(10) Pub. No.: US 2025/0212434 A1
(43) Pub. Date: Jun. 26, 2025

(54) SEMICONDUCTOR DEVICE AND POWER CONVERSION DEVICE

(71) Applicant: Minebea Power Semiconductor Device Inc., Ibaraki (JP)

(72) Inventor: Masaki SHIRAISHI, Hitachi-shi (JP)

(21) Appl. No.: 18/847,859

(22) PCT Filed: Dec. 13, 2022
(86) PCT No.: PCT/JP2022/045870

§ 371 Date: Sep. 17, 2024

(30) Foreign Application Priority Data
Mar. 30, 2022 (JP) 2022-054906

(51) Int. Cl. H10D 12/00; H10D 64/27; H10D 84/00

(52) U.S. Cl. CPC H10D 12/481; H10D 64/513; H10D 64/518; H10D 84/161

(57) ABSTRACT

A semiconductor device and power conversion device are provided in which the p-body layer area of a diode portion of an RC-IGBT is reduced, hole injection is suppressed, and the recovery characteristic is improved. The semiconductor device has first and second body layers and first trenches provided therebetween. First and second gate electrodes are formed on side walls on the first and second body layer sides, respectively, with a gate insulation film between the gate electrodes and body layer sides. The first and second gate electrodes are separated by a first insulation film. The diode has third and fourth body layers of a first conductivity type, and a second trench provided therebetween. The second trench has first and second electrodes formed on side walls on the third and fourth body layer sides, respectively, with insulation films therebetween and the first and second electrodes are separated by a second insulation film.

### TECHNICAL FIELD

The present invention relates to a semiconductor device and a power conversion device.

### BACKGROUND ART

The reverse conducting insulated gate bipolar transistor (IGBT) (hereafter, referred to as “RC-IGBT”), which incorporates IGBT and a diode in one chip, have the following advantages: (1) chip size can be reduced by sharing a termination region between the IGBT and the diode, and (2) thermal resistance is reduced because losses generated in the IGBT region or the diode region are dissipated throughout the entire chip. On the other hand, since the IGBT and the diode are fabricated in one chip, simultaneous optimization is difficult for each chip, and in particular, lifetime of the diode part is less likely to be controlled, leading to challenges of low injection and reduction in recovery loss in the diode.

For example, Patent Literature 1 provides a technique that addresses the challenge of low injection in the diode part of the RC-IGBT. Patent Literature 1 discloses a configuration of a semiconductor device, in which a plurality of first trenches 6 are provided in region A (IGBT region) while being equally spaced at a first interval, and a plurality of second trenches 10 are provided in region B (diode region) while being equally spaced at a second interval smaller than the first interval. According to the configuration of Patent Literature 1, since a larger number of trenches are provided in the region B (diode region), area of a P base layer 2, which serves as an anode of a diode when the diode is on, is relatively reduced, and thus hole injection from the P base layer 2 is suppressed, so that carrier density in the vicinity of a first main surface is reduced, making it possible to reduce peak current during recovery operation and improve recovery characteristics of the diode.

### CITATION LIST

### Patent Literature

Patent Literature 1: Japanese Unexamined Patent Application Publication No. 2008-53648

### SUMMARY OF INVENTION

### Technical Problem

In the method of the above Patent Literature 1, although hole injection is suppressed by reducing area of the P base layer 2 (p body layer) of the diode part of the RC-IGBT, since the area of the p-body layer is reduced by reducing the trench interval, there is a limit to reduction in area of the p-body layer due to limit of trench processing.

In view of the above circumstances, the invention provides a semiconductor device and a power conversion device, in each of which area of a p-body layer in a diode part of an RC-IGBT can be reduced to suppress hole injection, resulting in improvement in recovery characteristics.

### Solution to Problem

To solve the above problem, there is provided a semiconductor device as one aspect of the invention, the semiconductor device being RC-IGBT having an IGBT part and a diode part in one chip, where the IGBT part includes a first body layer and a second body layer, each layer having a first conductivity type, and a first trench provided between the first body layer and the second body layer, the first trench includes a first gate electrode formed on a sidewall on a side of the first body layer with a gate insulating film in between and a second gate electrode formed on a sidewall on a side of the second body layer with a gate insulating film in between, and the first gate electrode and the second gate electrode are separated from each other with at least a first insulating film in between, the diode part includes a third body layer and a fourth body layer, each layer having the first conductivity type, and a second trench provided between the third body layer and the fourth body layer, and the second trench includes a first electrode formed on a sidewall on a side of the third body layer with an insulating film in between and a second electrode formed on a sidewall on a side of the fourth body layer with an insulating film in between, and the first electrode and the second electrode are separated from each other with at least a second insulating film in between.

To solve the above problem, there is provided a power conversion device as another aspect of the invention, which includes a pair of DC terminals, AC terminals as many as AC output phases, switching legs as many as the AC output phases, which are connected between the pair of DC terminals and each include two parallel circuits connected in series, each parallel circuit including a switching element and a diode connected in antiparallel to the switching element, and gate circuits that each control the switching element, where the diode and the switching element are each the above semiconductor device.

More specific configurations of the invention are described in the claims.

### Advantageous Effects of Invention

According to the invention, it is possible to provide a semiconductor device and a power conversion device, in each of which area of a p-body layer in a diode part of RC-IGBT can be reduced to suppress hole injection, resulting in improvement in recovery characteristics.

Other problems, configurations, and effects will be clarified by the following description of one embodiment.

### BRIEF DESCRIPTION OF DRAWINGS

FIG. 1 is a schematic cross-sectional diagram showing a first example of a semiconductor device of the invention.

FIG. 2 is a schematic cross-sectional diagram showing a second example of the semiconductor device of the invention.

FIG. 3 is a schematic cross-sectional diagram showing a third example of the semiconductor device of the invention.

FIG. 4 is a circuit diagram showing a schematic configuration of a power conversion device of the invention.

### DESCRIPTION OF EMBODIMENTS

The invention will now be described in detail with reference to the drawings.

### [Semiconductor Device]

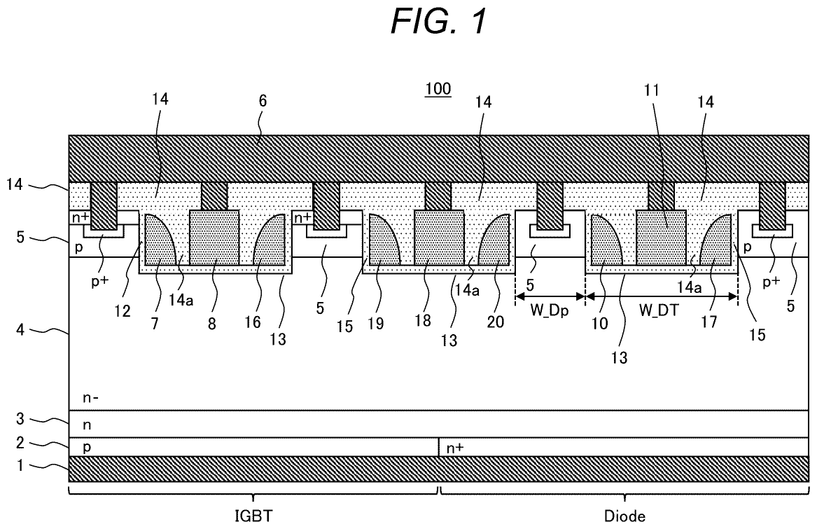

FIG. 1 is a schematic cross-sectional diagram showing a first example of a semiconductor device of the invention. As shown in FIG. 1, a semiconductor device (RC-IGBT) 100 of the invention has an IGBT part and a Diode part. The semiconductor device has a structure, in which a collector electrode layer/cathode electrode layer 1, a collector layer/cathode layer 2, a buffer layer 3, a drift layer 4, body layers 5, an insulating layer 14, and an emitter/anode electrode layer 6 are stacked from the back side toward the front side. The conductivity types “p” and “n” in FIG. 1 may be reversed.

Both the IGBT part and the Diode part have a front-surface-side structure including two body layers 5 and a trench 13 sandwiched between the body layers 5. The body layers in the IGBT part are referred to as a first body layer and a second body layer, and the body layers in the Diode part are referred to as a third body layer and a fourth body layer. A trench provided between the first and second body layers is referred to as a first trench, and a trench provided between the third and fourth body layers is referred to as a second trench.

In the trench 13 (first trench) in the IGBT part, a polysilicon gate electrode (first gate electrode) 7 is formed on a sidewall on the first-body-layer 5 side with a gate insulating film 12 in between. A polysilicon gate electrode (second gate electrode) 16 is formed on a sidewall on the second-body-layer 5 side with the gate insulating film 12 in between. The two gate electrodes 7 and 16 are separated from each other with an insulating film 14a, which is connected to the insulating film 14, in between, and a polysilicon emitter electrode 8 is formed between the two gate electrodes 7 and 16 while being separated from each of the gate electrodes 7 and 16 with the insulating film 14a in between and connected to the emitter/anode electrode layer 6.

In the trench 13 (second trench) in the Diode part, a polysilicon electrode (first electrode) 10 is formed on a sidewall on the third-body-layer 5 side with an insulating film 15 in between, and a polysilicon electrode (second electrode) 17 is formed on a sidewall on the fourth-body-layer 5 side with the insulating film 15 in between. The two electrodes 10 and 17 are separated from each other with an insulating film 14a in between, and a polysilicon anode electrode 11 is formed between the two gate electrodes 10 and 17 while being separated from each of the gate electrodes 10 and 17 with the insulating film 14a in between and connected to the emitter/anode electrode layer 6.

In the trench 13 (third trench) at the boundary between the IGBT part and the Diode part, a polysilicon electrode (third electrode) 19 is formed on a sidewall on the second-body-layer 5 side with the insulating film 15 in between, and a polysilicon electrode (fourth electrode) 20 is formed on a sidewall on the third-body-layer 5 side with the insulating film 15 in between. The two electrodes 19 and 20 are separated from each other with an insulating film 14a in between, and a polysilicon emitter/anode electrode 18 is formed between the gate electrodes 19 and 20 while being separated from each of the gate electrodes 19 and 20 with the insulating film 14a in between and connected to the emitter/anode electrode layer 6.

An n+ layer is provided in each of the first and second body layers in the IGBT part, while no n+ layer is provided in each of the third and fourth body layers in the Diode part.

The semiconductor device 100 shown in FIG. 1 is characterized in that width W_DT of the trench 13 is larger than width W_Dp of the body layer 5 in the Diode part. This makes it possible to reduce area of the body layer in the Diode part and thus suppress hole injection in the Diode part.

The IGBT part is covered with the thick insulating film 14a on its side opposite the body layer side, making it possible to reduce gate capacitance.

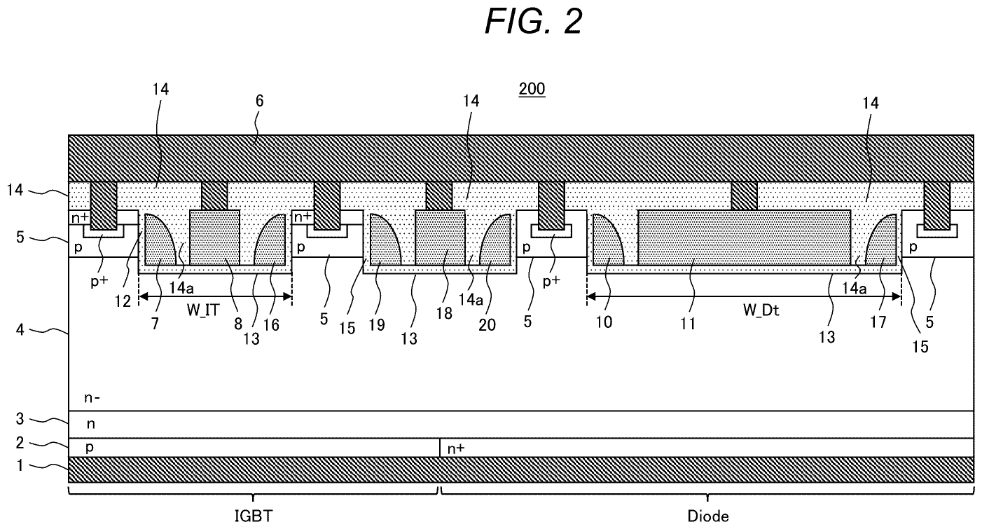

FIG. 2 is a schematic cross-sectional diagram showing a second example of the semiconductor device of the invention. The semiconductor device 200 shown in FIG. 2 is characterized in that width W_Dt of the trench 13 in the Diode part is different from width W_IT of the trench 13 in the IGBT part. As described above, the width W_Dt of the trench 13 in the diode part can be changed to change area of the body layer 5 so that hole injection is controlled, which makes it possible to adjust the tradeoff of forward voltage and recovery loss without lifetime control or the like and thus control the characteristics of the Diode part independently of the IGBT part.

Although W_Dt>W_IT is set in FIG. 2, W_IT>W_Dt may also be set.

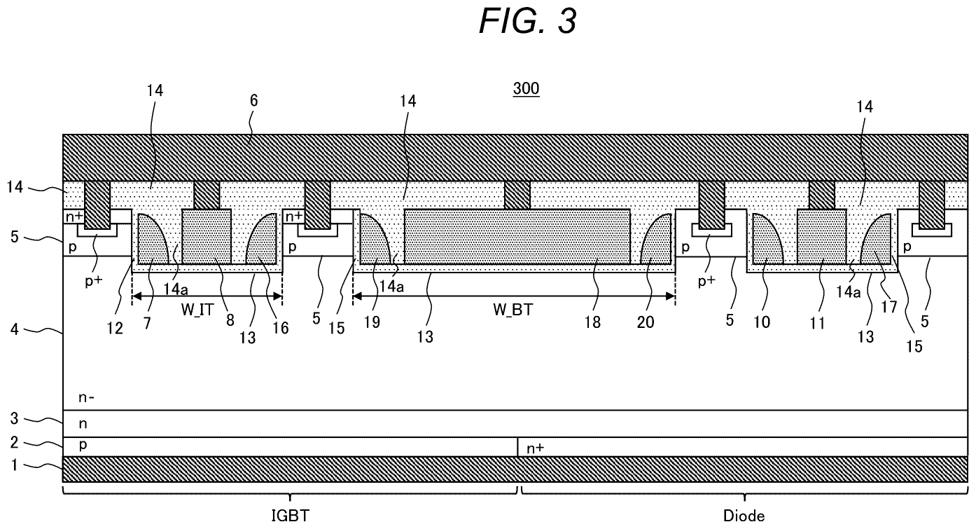

FIG. 3 is a schematic cross-sectional diagram showing a third example of the semiconductor device of the invention. The semiconductor device 300 shown in FIG. 3 is characterized in that width W_BT of the trench 13 provided at the boundary between the IGBT part and the Diode part is wider than the width W_IT of the trench 13 in the IGBT part.

In RC-IGBTs, holes may flow into the IGBT part at the boundary with the Diode part during recovery of the Diode part, causing element breakdown at the boundary. In the semiconductor device 300 shown in FIG. 3, therefore, the width W_BT of the trench 13 provided at the boundary between the Diode part and the IGBT part can be widened to increase a distance between the Diode part and the IGBT part, making it possible to suppress hole flowing into the IGBT part and thus suppress device breakdown.

### [Power Conversion Device]

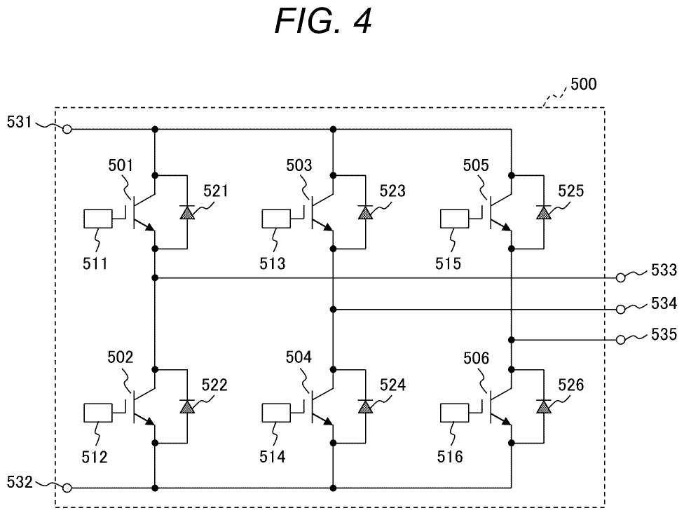

FIG. 4 is a circuit diagram showing a schematic configuration of a power conversion device of the invention. FIG. 4 shows an example of a circuit configuration of a power conversion device 500 of this embodiment and a connection relationship between a DC power source and a three-phase AC motor (AC load).

The power conversion device 500 of this embodiment uses at least one of the semiconductor devices of the invention for elements 501 to 506 and 521 to 526.

As shown in FIG. 4, the power conversion device 500 of this embodiment has a pair of DC terminals, i.e., a P terminal 531 and an N terminal 532, and AC terminals as many as AC output phases, i.e., a U terminal 533, a V terminal 534, and a W terminal 535.

The power conversion device 500 further includes a switching leg including a pair of power switching elements 501 and 502 connected in series and using a U terminal 533 for output that is connected to the series connection point of the power switching elements. The power conversion device 500 further includes a switching leg including a pair of power switching elements 503 and 504, having the same configuration as the power switching elements 501 and 502, connected in series and using a V terminal 534 for output that is connected to the series connection point of the power switching elements 503 and 504. The power conversion device 500 further includes a switching leg including a pair of power switching elements 505 and 506, which have the same configuration as the power switching elements 501 and 502, connected in series and using a W terminal 535 for output that is connected to the series connection point of the power switching elements 505 and 506.

The switching legs for the three phases, including the power switching elements 501 to 506, are connected between the DC terminals, i.e., the P terminal 531 and the N terminal 532, to receive DC power from an undepicted DC power supply. The three-phase AC terminals of the power conversion device 500, i.e., the U terminal 533, the V terminal 534, and the W terminal 535, are connected as terminals of a three-phase AC power supply to an undepicted three-phase AC motor.

Diodes 521 to 526 are connected in antiparallel to the power switching elements 501 to 506, respectively. Gate circuits 511 to 516 are connected to the respective input terminals of gates of the power switching elements 501 to 506, which each include, for example, IGBT, to control the power switching elements 501 to 506, respectively. The gate circuits 511 to 516 are integrally controlled by an integrated control circuit (not shown).

The power switching elements 501 to 506 are integrally and appropriately controlled by the gate circuits 511 to 516, so that DC power of a DC power supply Vcc is converted into three-phase AC power and output from the U terminal 533, the V terminal 534, and the W terminal 535.

Applying the semiconductor device (RC-IGBT) of the invention to the power conversion device 500 makes it possible to integrate the power switching elements 501 to 506 and the diodes 521 to 526 and thus achieve size reduction of the power conversion device. Furthermore, as described above, using the semiconductor device of the invention makes it possible to provide a power conversion device improved in recovery characteristics of the diode part.

As described above, it has been shown that the invention makes it possible to provide a semiconductor device and a power conversion device, in each of which, area of the p-body layer in the diode part of RC-IGBT can be reduced to suppress hole injection, resulting in improvement in recovery characteristics.

The invention is not limited to the above-described embodiment, but includes various modifications. For example, the above embodiment has been specifically described to give a clear description of the invention, but the invention is not necessarily limited to those with all the described configurations.

### REFERENCE SIGNS LIST

1: collector electrode layer/cathode electrode layer
2: collector layer/cathode layer
3: buffer layer
4: drift layer
5: body layer
6: emitter/anode electrode layer
7: gate electrode (first gate electrode)
8: polysilicon emitter electrode
10: polysilicon electrode (first electrode)
11: polysilicon anode electrode
12: gate insulating film
13: trench
14: insulating layer
14a, 15: insulating film
16: gate electrode (second gate electrode)
17: polysilicon electrode (second electrode)
18: polysilicon emitter/anode electrodes
19: polysilicon electrode (third electrode)
20: polysilicon electrode (fourth electrode)
100, 200, 300: semiconductor device
500: power conversion device
501 to 506: power switching element
511 to 516: gate circuit
521 to 526: diode
531: P terminal
532: N terminal
533: U Terminal
534: V terminal
535: W terminal

1. A semiconductor device, the semiconductor device being RC-IGBT comprising an IGBT part and a diode part in one chip,
wherein the IGBT part includes a first body layer and a second body layer, each layer having a first conductivity type, and a first trench provided between the first body layer and the second body layer,
the first trench includes a first gate electrode formed on a sidewall on a side of the first body layer with a gate insulating film in between and a second gate electrode formed on a sidewall on a side of the second body layer with a gate insulating film in between, and the first gate electrode and the second gate electrode are separated from each other with at least a first insulating film in between,
the diode part includes a third body layer and a fourth body layer, each layer having the first conductivity type, and a second trench provided between the third body layer and the fourth body layer, and
the second trench includes a first electrode formed on a sidewall on a side of the third body layer with an insulating film in between and a second electrode formed on a sidewall on a side of the fourth body layer with an insulating film in between, and the first electrode and the second electrode are separated from each other with at least a second insulating film in between.

2. The semiconductor device according to claim 1,
wherein width of the second trench is larger than width of each of the third and fourth body layers.

3. The semiconductor device according to claim 1,
wherein width of the first trench is different from width of the second trench.

4. The semiconductor device according to claim 1,
wherein a third trench is provided at a boundary between the IGBT part and the diode part, and width of the third trench is larger than width of the first trench.

5. A power conversion device, comprising:
a pair of DC terminals;
AC terminals as many as AC output phases;
switching legs as many as the AC output phases, the switching legs being connected between the pair of DC terminals and each including two parallel circuits connected in series, each parallel circuit including a switching element and a diode connected in antiparallel to the switching element; and
gate circuits that each control the switching element,
wherein the diode and the switching element are each the semiconductor device according to claim 1.
